(19) United States
(12) Patent Application Publication
(10) Pub. No.: US 2026/0078290 A1
(43) Pub. Date: Mar. 19, 2026

(54) CMP SLURRY FOR REDUCING POLISHING PAD WEAR RATE

(71) Applicant: Pureon, Inc., Monroe, NC (US)

(72) Inventors: Shane T. Finn, Charlotte, NC (US); William R. Gemmill, Indian Trail, NC (US); Keith H. Joye, Tabor City, NC (US); Terry M. Knight, Chandler, AZ (US); Caroline E. Watt, Charlotte, NC (US)

(21) Appl. No.: 19/333,089

(22) Filed: Sep. 18, 2025

Related U.S. Application Data
(60) Provisional application No. 63/695,943, filed on Sep. 18, 2024.

(51) Int. Cl. C09K 3/14; H01L 21/306

(52) U.S. Cl. CPC C09K 3/1463; H10P 52/402

(57) ABSTRACT

A chemical mechanical polishing (“CMP”) slurry is designed and configured for reducing polishing pad wear rate. The CMP slurry includes at least one oxidizer, a primary abrasive, a solvent, and a secondary abrasive. The secondary abrasive is a mixture of chemicals that yield a stable suspension of the CMP slurry. The CMP slurry for reducing polishing pad wear rate is designed and configured to provide a pad wear rate of less than 2.0% at a 1-hour polishing time, and/or a pad wear rate of less than 10.0% at a 4-hour polishing time.

### CROSS-REFERENCE TO RELATED APPLICATIONS

This application claims benefit to U.S. Provisional Patent Application No. 63/695,943 filed on Sep. 18, 2024, entitled “CMP Slurry for Reducing Pad Wear Rate”, which is incorporated by reference in its entirety.

### FIELD OF THE DISCLOSURE

The present disclosure relates to a polishing slurry for the polishing of hard substrates and materials. More specifically, the present disclosure is directed toward a polishing slurry containing abrasive particles and chemistries for the polishing of hard substrates such as silicon, silicon carbide (SiC), sapphire, diamond, gallium nitride (GaN), other hard semiconductor materials, or hard optical materials.

### BACKGROUND

Generally speaking, a polishing composition may be used for lapping or polishing a workpiece, like a workpiece made of silicon, silicon carbide (SiC), sapphire, diamond, gallium nitride (GaN), other hard semiconductor materials, or hard optical materials. The typical polishing composition is a water-based composition that may contain other co-solvents, abrasives, rheology modifiers, pH modifiers, oxidizers, and surfactants or dispersants. The manufacturing of SiC wafers requires that large, single crystals of SiC be grown, and from the single crystals, thin wafer blanks are obtained by wire-sawing or other methods such as laser cutting the single crystals. Subsequent processing is required to improve the surface finish and geometry of the wafers via mechanical polishing to the point where a final CMP step can be applied to remove subsurface damage from the previous mechanical polishing steps and provide the surface quality needed for subsequent use in creation of semiconductor or optical devices.

The typical polishing slurries used for CMP have both abrasives, for the mechanical removal, and chemistries, for inducing chemical changes at the surface of the hard material, which make it relatively softer and more conducive to removal by the abrasives. Both the abrasives and the chemistries also cause increased wear on typical polyurethane pads used during the CMP process. In many cases, the abrasives may be harder abrasives such as diamond, cubic boron nitride (CBN), boron carbide (B4C), silicon carbide (SiC), aluminum oxide (alumina), and zirconium oxide (zirconia), but can also be softer abrasives such as chromium oxide (chromia), cerium oxide (ceria), titanium dioxide (titania), or silicon dioxide (silica). The harder abrasives induce increased mechanical pad wear, but the softer abrasives can also wear the pads mechanically.

Furthermore, the chemicals of the CMP process, like the use of acids or bases to modify the pH of the slurry, can chemically degrade the pad, allowing for more mechanical deterioration over time during the CMP process. The use of oxidizers such as peroxides, persulfates, manganates, permanganates, iodates, periodates, chlorates, bromates, nitrates, and others, can also chemically degrade the pad, allowing for more mechanical deterioration over time during the CMP process.

Pad lifetimes are impacted by several factors, including but not limited to chemistry and composition of the slurry, extreme process conditions, and aggressive conditioning parameters to maintain a consistent process. CMP slurry chemistry is necessarily oxidizing, to convert the hard surface to a softer oxide so that it can be mechanically swept away by abrasives (ranging from hard to soft) and the polishing action of the pad. Also, many slurries have been optimized to operate at more extreme pH ranges, or with other additives, because these tend to act faster on recalcitrant surfaces, increasing material removal rate (MRR), decreasing surface roughness (typically evaluated by average line profile roughness, Ra, or root mean square height area roughness, Sq) and reducing process time. Finally, higher process parameters such as pressure, velocity (pressure and velocity are often combined into pressure-velocity or “PV”) and temperature, will all contribute to increasing pad wear.

One issue with the prior art is degradation of polishing pads during the CMP step, resulting in very limited pad lifetimes. Increased pad lifetime involved in the CMP step to prepare an epi-ready surface decreases cost of ownership by using fewer pads and reduced down time due to a lower frequency of changing pads. One example of prior art uses low pH, nitric acid, and salts of chloric acids to reduce process temperature, achieving very high material removal rate (MRR) to greater than 13 μm/h, sub-angstrom surfaces, and even claims to reduce residue on the pad thus increasing pad life (see US Patent Publication No. 2022/0315802A, which is incorporated herein, by reference, in its entirety). However, this prior art disclosure does not provide any measure of residue or evidence that pad life is increased. Another example of prior art achieves roughness less than 5 Å with a platy-shaped, softer abrasive less than 500 nm, harder abrasive (see US Patent Publication No. US2024/0053301, which is incorporated herein, by reference, in its entirety). A third example of prior art achieves a relatively higher removal rate without increasing the polishing temperature (see U.S. Pat. No. 12,139,643, which is incorporated herein, by reference, in its entirety). However, none of these examples from the prior art address the issue of pad wear.

The instant disclosure may be designed to address at least certain aspects of the problems or needs discussed above by providing a CMP slurry for reducing polishing pad wear rate.

### SUMMARY

The present disclosure may solve the aforementioned limitations of the currently available polishing slurries by providing the disclosed chemical mechanical processing slurry for reducing polishing pad wear rate, or referred to herein, as just CMP slurry. The disclosed CMP slurry for reducing polishing pad wear rate may be designed and configured for reducing polishing pad wear rate. The disclosed CMP slurry for reducing polishing pad wear rate may generally include at least one oxidizer, a primary abrasive, a solvent, and a secondary abrasive. The secondary abrasive function may be a mixture of chemicals that yield a stable suspension of the CMP slurry.

In select embodiments, the disclosed CMP slurry for reducing polishing pad wear rate may be designed and configured to provide a pad wear rate of less than 2.0% at a 1-hour polishing time.

In other select embodiments, the disclosed CMP slurry for reducing polishing pad wear rate may be designed and configured to provide a pad wear rate of less than 10.0% at a 4-hour polishing time.

In other select embodiments, the disclosed CMP slurry for reducing polishing pad wear rate may be designed and configured to provide a pad wear rate of less than 2.0% at a 1-hour polishing time, and a pad wear rate of less than 10.0% at a 4-hour polishing time.

In select embodiments, the disclosed CMP slurry for reducing polishing pad wear rate may be designed and configured to provide a pad wear rate of less than 1.0% at a 1-hour polishing time.

In other select embodiments, the disclosed CMP slurry for reducing polishing pad wear rate may be designed and configured to provide a pad wear rate of less than 3.0% at a 4-hour polishing time.

In other select embodiments, the disclosed CMP slurry for reducing polishing pad wear rate may be designed and configured to provide a pad wear rate of less than 1.0% at a 1-hour polishing time, and a pad wear rate of less than 3.0% at a 4-hour polishing time.

In select embodiments, the disclosed CMP slurry for reducing polishing pad wear rate may be designed and configured to provide a pad wear rate of less than 0.1% at a 1-hour polishing time.

In other select embodiments, the disclosed CMP slurry for reducing polishing pad wear rate may be designed and configured to provide a pad wear rate of less than 1.5% at a 4-hour polishing time.

In other select embodiments, the disclosed CMP slurry for reducing polishing pad wear rate may be designed and configured to provide a pad wear rate of less than 0.1% at a 1-hour polishing time, and a pad wear rate of less than 1.5% at a 4-hour polishing time.

One feature of the disclosed CMP slurry for reducing polishing pad wear rate may be that it can be designed and configured to provide a reduced pad wear rate compared to a standard CMP slurry. The disclosed CMP slurry may be designed and configured to provide the reduced pad wear rate compared to the standard CMP slurry while providing a material removal rate (MRR) and a surface roughness (S_{q}) of a workpiece post-polish. In select embodiments, the CMP slurry may be designed and configured to provide the reduced pad wear rate, where the pad wear rate is reduced by 50% or more compared to the standard CMP slurry, while the material removal rate (MRR) is greater than 4.0 μm/h for a 1-hour polish time, and the surface roughness (S_{q}) of the workpiece post-polish is less than 2.0 Å. In other select embodiments, the disclosed CMP slurry for reducing polishing pad wear rate may be designed and configured to reduce the pad wear rate by 75% or more compared to the standard CMP slurry, while the material removal rate (MRR) is greater than 4.5 μm/h for a 1-hour polish time, and the surface roughness (S_{q}) of the workpiece post-polish is less than 1.5 Å.

In select embodiments of the disclosed CMP slurry for reducing polishing pad wear rate, the at least one oxidizer may be, but is clearly not limited thereto, a permanganate, a perborate, a periodate, a persulfate, a peroxide, a perchlorate, a chlorate, a chlorite, a hypochlorite, a nitrate, a peroxo-compound, or a combination thereof.

In select embodiments of the disclosed CMP slurry for reducing polishing pad wear rate, the secondary abrasive of the mixture of chemicals that yield the stable suspension may be, but is clearly not limited thereto, a boehmite, a fumed silica, or a combination thereof.

In select embodiments of the disclosed CMP slurry for reducing polishing pad wear rate, the primary abrasive may be, but is clearly not limited thereto, a diamond, an alumina, a boron carbide, a silicon carbide, a cerium oxide, a zirconium oxide, a silica, an aluminum oxide hydroxide, a boron nitride, a garnet, a walnut shell, a kaolin, a gibbsite, a titania, a mica, an aluminum bromide, a boron hydride, a magnesium hydroxide, or a combination thereof.

In select embodiments of the disclosed CMP slurry for reducing polishing pad wear rate, the solvent may be, but is clearly not limited thereto, a water. The water may include deionized water.

In select embodiments of the disclosed CMP slurry for reducing polishing pad wear rate: the at least one oxidizer may be the permanganate, the perborate, the periodate, the persulfate, the peroxide, the perchlorate, the chlorate, the chlorite, the hypochlorite, the nitrate, the peroxo-compound, or the combination thereof; the secondary abrasive of the mixture of chemicals that yield the stable suspension may be the boehmite, the fumed silica, or the combination thereof; the primary abrasive may be the diamond, the alumina, the boron carbide, the silicon carbide, the cerium oxide, the zirconium oxide, the silica, the aluminum oxide hydroxide, the boron nitride, the garnet, the walnut shell, the kaolin, the gibbsite, the titania, the mica, the aluminum bromide, the boron hydride, the magnesium hydroxide, or the combination thereof; and the solvent may be the water including the deionized water.

In select embodiments of the disclosed CMP slurry for reducing polishing pad wear rate, the at least one oxidizer may be 0.1-50% by weight of the CMP slurry.

In select embodiments of the disclosed CMP slurry for reducing polishing pad wear rate, the secondary abrasive of the mixture of chemicals that yield the stable suspension may be 0.01-5% by weight of the CMP slurry.

In select embodiments of the disclosed CMP slurry for reducing polishing pad wear rate, the primary abrasive may be 0.01-10% by weight of the CMP slurry. In select embodiments, the primary abrasive may have a particle size of 0.01-10 microns.

In select embodiments of the disclosed CMP slurry for reducing polishing pad wear rate, the solvent may be 35-99.88% by weight of the CMP slurry.

In select embodiments of the disclosed CMP slurry for reducing polishing pad wear rate: the at least one oxidizer may be 0.1-50% by weight of the CMP slurry; the secondary abrasive of the mixture of chemicals that yield the stable suspension may be 0.01-5% by weight of the CMP slurry; the primary abrasive may be 0.01-10% by weight of the CMP slurry; and the solvent may be 35-99.88% by weight of the CMP slurry. In select embodiments, and clearly not limited thereto, the at least one oxidizer may be approximately or equal to 3.0% by weight of the CMP slurry; the secondary abrasive of the mixture of chemicals that yield the stable suspension may be approximately or equal to 0.9% by weight of the CMP slurry; the primary abrasive may be approximately or equal to 3.0% by weight of the CMP slurry; and the solvent may be approximately or equal to 93.1% by weight of the CMP slurry. In select embodiments of the disclosed CMP slurry, and clearly not limited thereto: the at least one oxidizer may be 3.0% by weight of the CMP slurry; the secondary abrasive of the mixture of chemicals that yield the stable suspension may be 0.9% by weight of the CMP slurry and is a combination of a boehmite at 0.6% by weight of the CMP slurry and a fumed silica at 0.3% by weight of the CMP slurry; the primary abrasive may be at 3.0% by weight of the CMP slurry; and the solvent may be water at 93.1% by weight of the CMP slurry. In select embodiments of the disclosed CMP slurry, and clearly not limited thereto: the at least one oxidizer may be a potassium permanganate at approximately or equal to 3.0% by weight of the CMP slurry and an aluminum nitrate at approximately or equal to 0.50% by weight of the CMP slurry; the secondary abrasive of the mixture of chemicals that yield the stable suspension may be a boehmite alumina at approximately or equal to 0.78% by weight of the CMP slurry and a fumed silica at approximately or equal to 0.3% by weight of the CMP slurry; the primary abrasive may be an alpha alumina at approximately or equal to 4.3% by weight of the CMP slurry; and the solvent may be deionized water at approximately or equal to 88.7% by weight of the CMP slurry. In select embodiments of the disclosed CMP slurry, and clearly not limited thereto: the at least one oxidizer may be a potassium permanganate at 3.0% by weight of the CMP slurry and an aluminum nitrate at 0.50% by weight of the CMP slurry; the secondary abrasive of the mixture of chemicals that yield the stable suspension may be a boehmite alumina at 0.78% by weight of the CMP slurry and a fumed silica at 0.3% by weight of the CMP slurry; the primary abrasive may be an alpha alumina at 4.3% by weight of the CMP slurry; and the solvent may be deionized water at 91.12% by weight of the CMP slurry.

Another feature of the disclosed CMP slurry for reducing polishing pad wear rate may be that it can be designed and configured to contain abrasive particles at neutral pH for the polishing of hard substrates such as silicon, silicon carbide (SiC), sapphire, diamond, gallium nitride (GaN) or other materials with a Knoop hardness greater than or equal to 1000 used in combination with polyurethane pads. In select embodiments, the hard substrates may have a Knoop hardness greater than or equal to 2000 used in combination with polyurethane pads.

Another feature of the disclosed CMP slurry for reducing polishing pad wear rate may be that it can be designed and configured to improve compatibility between the slurry composition and the pad, wherein the use of the disclosed CMP slurry which requires less extreme pH and fewer additives allows for the realization of lower pad wear rate while maintaining an acceptable material removal rate (MRR) and surface roughness (S_{q}).

In another aspect, the instant disclosure embraces the disclosed CMP slurry in any of the various embodiments and/or combination of embodiments shown and/or described herein.

In another aspect, the instant disclosure embraces a method of chemical mechanical polishing (“CMP”) of a hard substrate. The disclosed method of CMP of a hard substrate may include utilizing the disclosed CMP slurry in any of the various embodiments and/or combination of embodiments shown and/or described herein. As such, the disclosed method of CMP of a hard substrate may generally include providing the disclosed CMP slurry in any of the various embodiments and/or combination of embodiments shown and/or described herein. In general, the provided CMP slurry may include at least one oxidizer, a primary abrasive, a solvent, and a secondary abrasive that is a mixture of chemicals that yield a stable suspension. With the provided CMP slurry, the disclosed method of CMP of a hard substrate may further include polishing the hard substrate with the provided CMP slurry. Wherein the CMP slurry may be designed and configured to provide: a pad wear rate of less than 2.0% at a 1-hour polishing time; a pad wear rate of less than 10.0% at a 4-hour polishing time; or a combination thereof. In select embodiments of the method of CMP of the hard substrate, the hard substrate may be a workpiece made of silicon, silicon carbide (SiC), sapphire, diamond, gallium nitride (GaN), other hard semiconductor materials, or hard optical materials, wherein the workpiece having a Knoop hardness greater than or equal to 1000. In select embodiments, the hard substrate of the workpiece may have a Knoop hardness greater than or equal to 2000 used in combination with polyurethane pads. In select embodiments of the method of CMP of the hard substrate, the disclosed CMP slurry may be used with polyurethane pads for polishing the workpiece.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

The present disclosure will be better understood by reading the Detailed Description with reference to the accompanying drawings, which are not necessarily drawn to scale, and in which like reference numerals denote similar structure and refer to like elements throughout, and in which:

FIG. 1A shows a plot line graph of comparative examples for state of the art slurries from the prior art showing pad thickness after various CMP processes;

FIG. 1B shows a plot line graph of a CMP slurry (“IC” is shown for the disclosed Inventive Composition) for reducing polishing pad wear rate according to select embodiments of the instant disclosure showing pad thickness after various CMP processes;

FIG. 2 shows a plot line graph of a CMP slurry (“IC” is shown for the disclosed Inventive Composition) for reducing polishing pad wear rate according to select embodiments of the instant disclosure showing pad wear after extended polishing time with the IC slurry;

FIG. 3 is an image of roughness measurements of a SiC wafer after polishing with a state of the art slurry from the prior art, Comparative Example Y;

FIG. 4 shows an image of roughness measurements of a SiC wafer after polishing with a state of the art slurry from the prior art, Comparative Example X;

FIG. 5 shows an image of roughness measurements of a SiC wafer after polishing with a CMP slurry for reducing polishing pad wear rate according to select embodiments of the instant disclosure; and

FIG. 6 shows a bar graph for pad material removal comparison of a comparative Example Z from the prior art and a CMP slurry (“IC” is shown for the disclosed Inventive Composition) for reducing polishing pad wear rate according to select embodiments of the instant disclosure showing pad wear results of direct pad wear polishing tests.

It is to be noted that the drawings presented are intended solely for the purpose of illustration and that they are, therefore, neither desired nor intended to limit the disclosure to any or all of the exact details of construction shown, except insofar as they may be deemed essential to the claimed disclosure.

### DETAILED DESCRIPTION

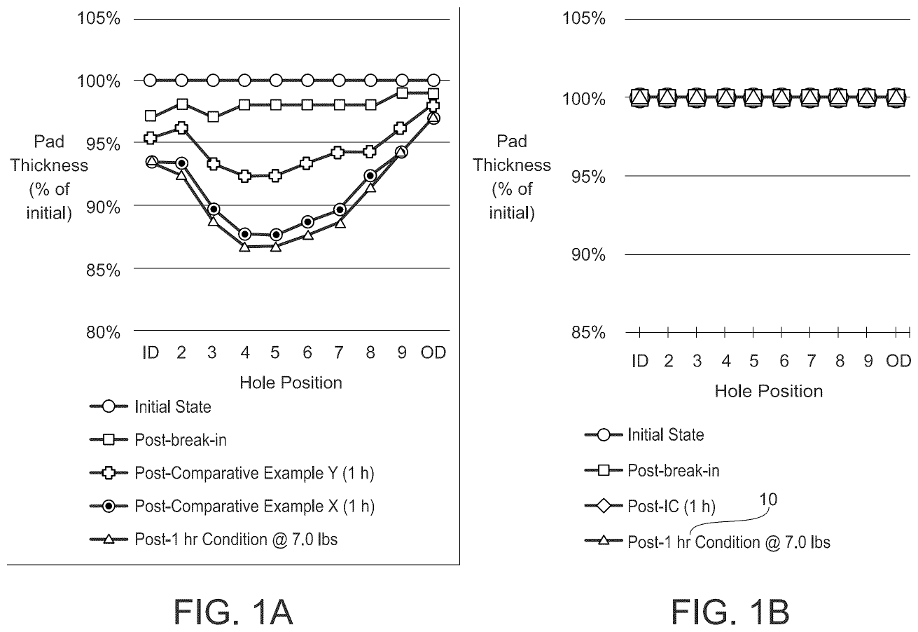

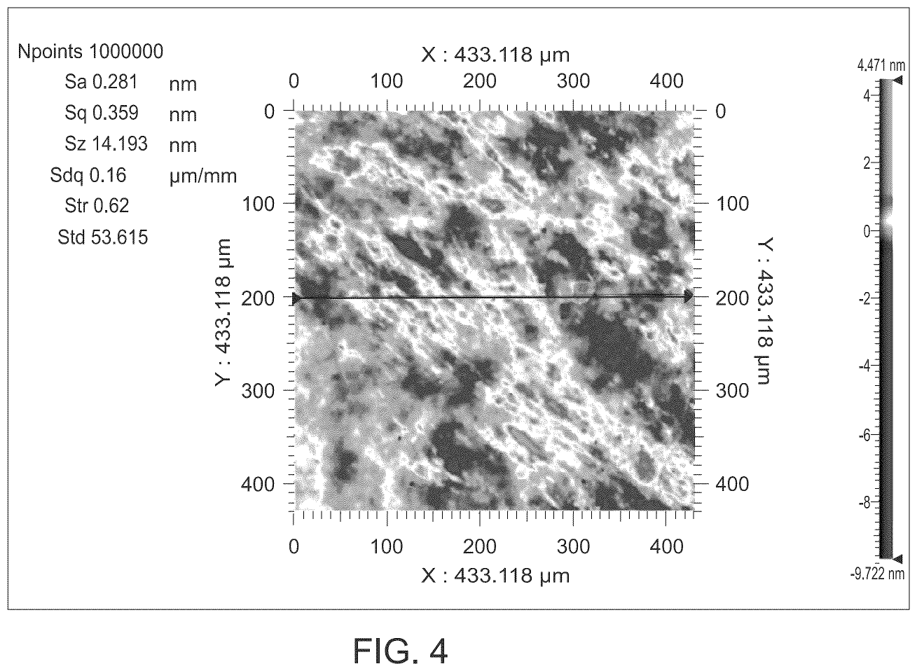

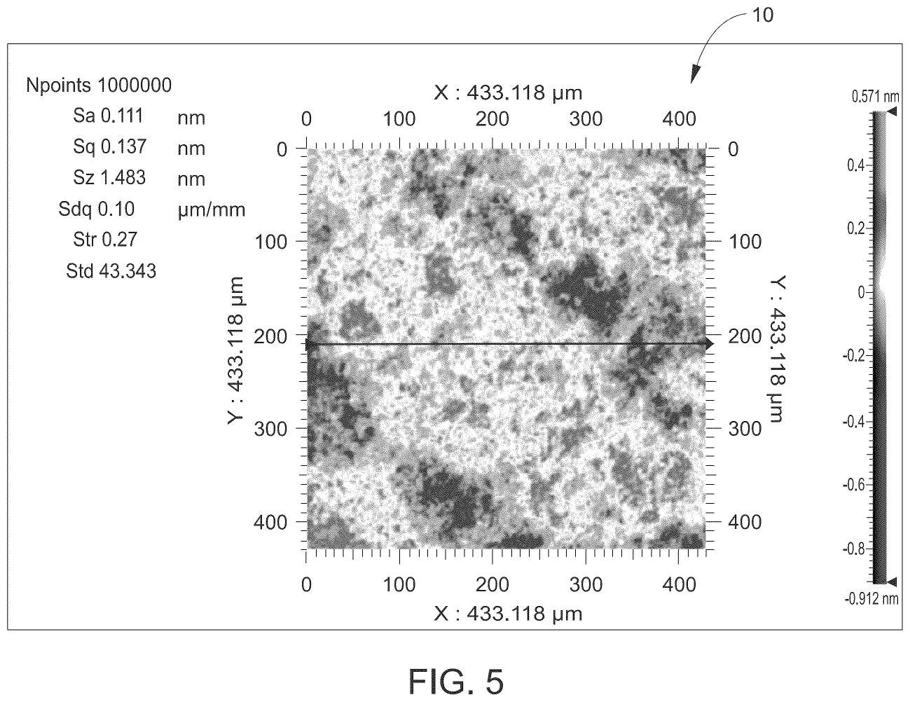

Referring now to FIGS. 1-6, in describing the exemplary embodiments of the present disclosure, specific terminology is employed for the sake of clarity. The present disclosure, however, is not intended to be limited to the specific terminology so selected, and it is to be understood that each specific element includes all technical equivalents that operate in a similar manner to accomplish similar functions. Embodiments of the claims may, however, be embodied in many different forms and should not be construed to be limited to the embodiments set forth herein. The examples set forth herein are non-limiting examples and are merely examples among other possible examples.

Referring to FIGS. 1-6, the present disclosure may solve the aforementioned limitations of the currently available polishing slurries by providing the disclosed CMP slurry 10. CMP slurry 10 may be designed and configured for reducing polishing pad wear rate. CMP slurry 10 may generally include at least one oxidizer, a primary abrasive, a solvent, and a secondary abrasive. The secondary abrasive may be a mixture of chemicals that yield a stable suspension of the CMP slurry 10.

In select embodiments, CMP slurry 10 for reducing polishing pad wear rate may be designed and configured to provide a pad wear rate of less than 2.0% at a 1-hour polishing time, and/or a pad wear rate of less than 10.0% at a 4-hour polishing time.

In select embodiments, CMP slurry 10 for reducing polishing pad wear rate may be designed and configured to provide a pad wear rate of less than 1.0% at a 1-hour polishing time, and/or a pad wear rate of less than 3.0% at a 4-hour polishing time.

In select embodiments, CMP slurry 10 for reducing polishing pad wear rate may be designed and configured to provide a pad wear rate of less than 0.1% at a 1-hour polishing time, and/or a pad wear rate of less than 1.5% at a 4-hour polishing time.

One feature of CMP slurry 10 for reducing polishing pad wear rate may be that it can be designed and configured to provide a reduced pad wear rate compared to a standard CMP slurry. Sec FIGS. 1-2 and 6. CMP slurry 10 may be designed and configured to provide the reduced pad wear rate compared to the standard CMP slurry while providing a material removal rate (MRR) and a surface roughness (S_{q}) of a workpiece post-polish. In select embodiments, CMP slurry 10 may be designed and configured to reduce the pad wear rate by at least 50% compared to the standard CMP slurry, while the material removal rate (MRR) is greater than 4.0 μm/h for a 1-hour polish time, and the surface roughness (S_{q}) of the workpiece post-polish is less than 2.0 Å. In other select embodiments, CMP slurry 10 for reducing polishing pad wear rate may be designed and configured to reduce the pad wear rate by at least 75% compared to the standard CMP slurry, while the material removal rate (MRR) is greater than 4.5 μm/h for a 1-hour polish time, and the surface roughness (S_{q}) of the workpiece post-polish is less than 1.5 Å.

In select embodiments of CMP slurry 10 for reducing polishing pad wear rate, the at least one oxidizer may be, but is clearly not limited thereto, a permanganate, a perborate, a periodate, a persulfate, a peroxide, a perchlorate, a chlorate, a chlorite, a hypochlorite, a nitrate, a peroxo-compound, or a combination thereof.

In select embodiments of CMP slurry 10 for reducing polishing pad wear rate, the secondary abrasive of the mixture of chemicals that yield the stable suspension may be, but is clearly not limited thereto, a boehmite, a fumed silica, the like, and/or various combinations thereof.

In select embodiments of CMP slurry 10 for reducing polishing pad wear rate, the primary abrasive may be, but is clearly not limited thereto, a diamond, an alumina, a boron carbide, a silicon carbide, a cerium oxide, a zirconium oxide, a silica, an aluminum oxide hydroxide, a boron nitride, a garnet, a walnut shell, a kaolin, a gibbsite, a titania, a mica, an aluminum bromide, a boron hydride, a magnesium hydroxide, the like, and/or various combination thereof.

In select embodiments of CMP slurry 10 for reducing polishing pad wear rate, the solvent may be, but is clearly not limited thereto, a water. The water may include a deionized water.

In select embodiments of CMP slurry 10 for reducing polishing pad wear rate: the at least one oxidizer may be the permanganate, the perborate, the periodate, the persulfate, the peroxide, the perchlorate, the chlorate, the chlorite, the hypochlorite, the nitrate, the peroxo-compound, the like, and/or the various combinations thereof; the secondary abrasive of the mixture of chemicals that yield the stable suspension may be the boehmite, the fumed silica, the like, and/or the various combinations thereof; the primary abrasive may be the diamond, the alumina, the boron carbide, the silicon carbide, the cerium oxide, the zirconium oxide, the silica, the aluminum oxide hydroxide, the boron nitride, the garnet, the walnut shell, the kaolin, the gibbsite, the titania, the mica, the aluminum bromide, the boron hydride, the magnesium hydroxide, the like, and/or the various combination thereof; and the solvent may be the water including the deionized water.

In select embodiments of CMP slurry 10 for reducing polishing pad wear rate, the at least one oxidizer may be 0.1-50% by weight of CMP slurry 10.

In select embodiments of CMP slurry 10 for reducing polishing pad wear rate, the secondary abrasive of the mixture of chemicals that yield the stable suspension may be 0.01-5% by weight of CMP slurry 10.

In select embodiments of CMP slurry 10 for reducing polishing pad wear rate, the primary abrasive may be 0.01-10% by weight of CMP slurry 10. In select embodiments, the primary abrasive may have a particle size of 0.01-10 microns.

In select embodiments of CMP slurry 10 for reducing polishing pad wear rate, the solvent may be 35-99.88% by weight of CMP slurry 10

In select embodiments of CMP slurry 10 for reducing polishing pad wear rate: the at least one oxidizer may be 0.1-50% by weight of CMP slurry 10; the secondary abrasive of the mixture of chemicals that yield the stable suspension may be 0.01-5% by weight of CMP slurry 10; the primary abrasive may be 0.01-10% by weight of CMP slurry 10; and the solvent may be 35-99.88% by weight of CMP slurry 10. In select embodiments, and clearly not limited thereto, the at least one oxidizer may be approximately or equal to 3.0% by weight of CMP slurry 10; the secondary abrasive of the mixture of chemicals that yield the stable suspension may be approximately or equal to 0.9% by weight of CMP slurry 10; the primary abrasive may be approximately or equal to 3.0% by weight of CMP slurry 10; and the solvent may be approximately or equal to 93.1% by weight of CMP slurry 10. In select embodiments of CMP slurry 10, and clearly not limited thereto: the at least one oxidizer may be 3.0% by weight of CMP slurry 10; the secondary abrasive of the mixture of chemicals that yield the stable suspension may be 0.9% by weight of CMP slurry 10 and is a combination of a boehmite at 0.6% by weight of CMP slurry 10 and a fumed silica at 0.3% by weight of CMP slurry 10; the primary abrasive may be at 3.0% by weight of CMP slurry 10; and the solvent may be water at 92.2% by weight of CMP slurry 10. In select embodiments of CMP slurry 10, and clearly not limited thereto: the at least one oxidizer may be a potassium permanganate at approximately or equal to 3.0% by weight of CMP slurry 10 and an aluminum nitrate at approximately or equal to 0.50% by weight of CMP slurry 10; the secondary abrasive of the mixture of chemicals that yield the stable suspension may be a boehmite alumina at approximately or equal to 0.78% by weight of CMP slurry 10 and a fumed silica at approximately or equal to 0.3% by weight of CMP slurry 10; the primary abrasive may be an alpha alumina at approximately or equal to 4.3% by weight of CMP slurry 10; and the solvent may be deionized water at approximately or equal to 91.12% by weight of CMP slurry 10. In select embodiments of CMP slurry 10, and clearly not limited thereto: the at least one oxidizer may be a potassium permanganate at 3.0% by weight of CMP slurry 10 and an aluminum nitrate at 0.50% by weight of CMP slurry 10; the secondary abrasive of the mixture of chemicals that yield the stable suspension may be a boehmite alumina at 0.78% by weight of CMP slurry 10 and a fumed silica at 0.3% by weight of CMP slurry 10; the primary abrasive may be an alpha alumina at 4.3% by weight of CMP slurry 10; and the solvent may be deionized water at 91.12% by weight of CMP slurry 10.

Another feature of CMP slurry 10 for reducing polishing pad wear rate may be that it can be designed and configured to contain abrasive particles at neutral pH for the polishing of hard substrates such as silicon carbide (SiC), sapphire, diamond, gallium nitride (GaN) or other materials with a Knoop hardness greater than or equal to 1000 used in combination with polyurethane pads. In select embodiments, the hard substrates may have a Knoop hardness greater than or equal to 2000 used in combination with polyurethane pads.

Another feature of CMP slurry 10 for reducing polishing pad wear rate may be that it can be designed and configured to improve compatibility between the slurry composition and the pad, wherein the use of CMP slurry 10 which requires less extreme pH and fewer additives allows for the realization of lower pad wear rate while maintaining an acceptable material removal rate (MRR) and surface roughness (S_{q}).

In another aspect, the instant disclosure embraces a method of chemical mechanical polishing (“CMP”) of a hard substrate. The disclosed method of CMP of a hard substrate may include utilizing CMP slurry 10 in any of the various embodiments and/or combination of embodiments shown and/or described herein. As such, the disclosed method of CMP of a hard substrate may generally include providing CMP slurry 10 in any of the various embodiments and/or combination of embodiments shown and/or described herein. In general, the provided CMP slurry 10 may include at least one oxidizer, a primary abrasive, a solvent, and a secondary abrasive that is a mixture of chemicals that yield a stable suspension. With the provided CMP slurry 10, the disclosed method of CMP of a hard substrate may further include polishing the hard substrate with the provided CMP slurry 10. Wherein, CMP slurry 10 may be designed and configured to provide: a pad wear rate of less than 2.0% at a 1-hour polishing time; a pad wear rate of less than 10.0% at a 4-hour polishing time; or a combination thereof. In select embodiments of the method of CMP of the hard substrate, the hard substrate may be a workpiece made of silicon, silicon carbide (SiC), sapphire, diamond, gallium nitride (GaN), other hard semiconductor materials, or hard optical materials, wherein the workpiece having a Knoop hardness greater than or equal to 2000. In select embodiments, the hard substrates of the workpiece may have a Knoop hardness greater than or equal to 2000 used in combination with polyurethane pads. In select embodiments of the method of CMP of the hard substrate, CMP slurry 10 may be used with polyurethane pads for polishing the workpiece.

CMP slurry 10, as disclosed herein, may solve the limitations of the currently available CMP slurries via improved compatibility between the slurry composition and the pad. The use of a unique slurry composition which requires less extreme pH and fewer additives allows for the realization of lower pad wear rate while maintaining the material removal rate (MRR) and surface roughness (S_{q}). CMP slurry 10 may provide adequate material removal rates, a desirable lower roughness surface (S_{q}) of the workpiece post-polish, and significantly reduced pad wear (see Table 1 below).

TABLE 1
Comparison of slurry performance.

| | For 1 hour | | For Indicated | |
|---|---|---|---|---|
| | Polish time | | Polish time | |
| | MRR | | Pad | Polish |
| | (μm/h)* | S_{q} (Å)** | Wear*** | Time (h) |
| Comparative Example X | 5.25 | 4.60 | 3.48% | 1 |
| Comparative Example Y | 5.78 | 3.23 | 3.20% | 1 |
| IC | 4.65 | 1.48 | <0.1% | 1 |
| | | | 1.30% | 4 |

Notes from table:
*MRR was calculated by measuring weight of the wafer before and after CMP, converting this weight to thickness of the wafer, and dividing that by the amount of time polished.
**Surface roughness (S_{q}) was determined using a Zygo Zegage HR Pro with a 20x objective lens. The XY origin was set at left side of major flat when oriented parallel with the bottom of the camera image. The same coordinates were used for three spots - “center,” “middle,” and “edge” - each time. The raw data were digitally processed to remove artifacts arising from variations in stage height and light source. The values of Sq in nm for each spot were averaged, then converted to Å.
***Pad wear was calculated by dividing each set of hole measurements by their initial thickness, subtracting that value from 1, and averaging values for that set of conditions. Comparative Example Y was the Fujimi 223 slurry, from Fujimi Corporation of Wilsonville, Oregon. Comparative Example X was the Entegris G7 slurry, from Entegris of Billerica, MA. CMP slurry 10, or the inventive composition (“IC”) shown in the table included: Water (93.1%); Oxidizer (3%);
• Primary Abrasive (3%); and Secondary Abrasive(s)/Suspension aid (0.6% boehmite + 0.3% fumed silica).

Referring to Table 1 above and FIGS. 1-5, the polishing of SiC wafers was performed on an IPEC 472 polisher using 150 mm diameter wafers and a 22.5-inch diameter Ikonic 4250L polishing pad from Pureon, Inc. of Monroe, NC The downforce in the process was 6.5 psi with 1.3 psi back pressure (7.9 psi total) and the polishing head was rotating at 109 rpm and the platen was rotating at 125 rpm. The slurry was delivered to the pad surface at a rate of 75 mL/min to maintain adequate slurry coverage across the pad. The pad wear was determined by first punching ten holes (could be done with other numbers of holes) across the radius of the pad from the inner diameter to the outer diameter. Then, the pad thickness was measured before and after pad break-in and after each CMP run using a drop gauge.

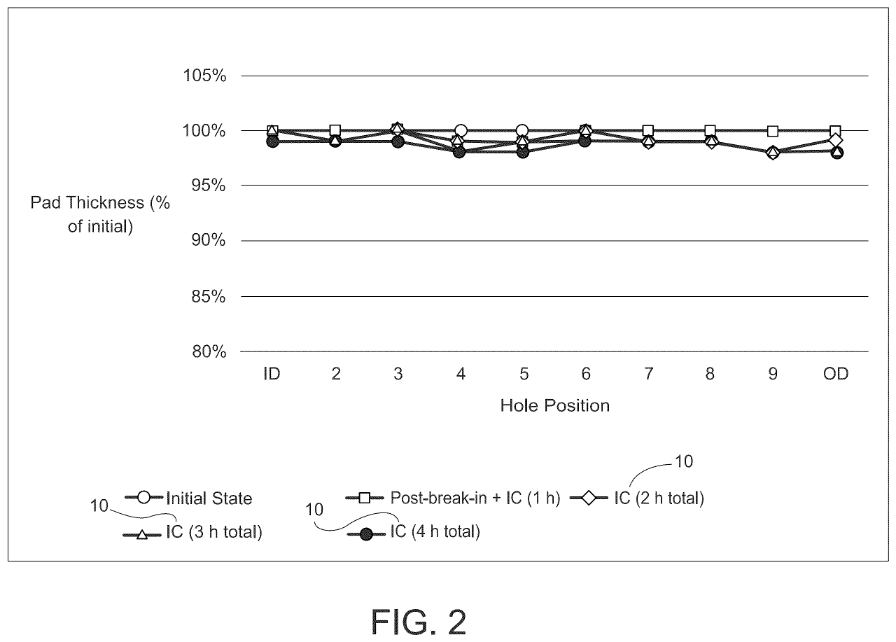

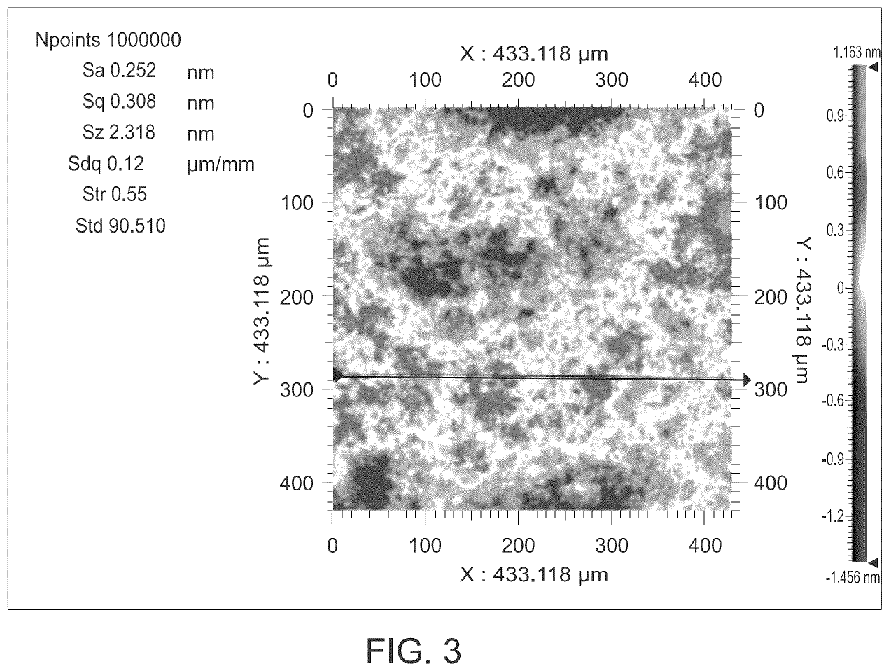

Referring specifically to FIGS. 1-5, CMP slurry, or the inventive composition (IC) provides an incredible improvement in pad wear (0%-see FIG. 1B). Even after extended runs of 4 hours (FIG. 2), the pad does not wear more than 1.3%. CMP slurry 10 achieves this while maintaining a competitive material removal rate (MRR) of 4.65 μm/h and surface roughness (S_{q}) of 1.48 Å (see Table 1) or approximately 2 Å. Representative measurements of surface roughness (S_{q}) for each slurry are provided in FIGS. 3-5. The advantages of CMP slurry 10 are readily apparent and most notably are the improvement in pad wear rate and therefore a decrease in process cost of ownership. For this example, we employed unadjusted pH of the composition, but the options could be quite endless in that the optimized pH, abrasive type(s), concentrations, etc., have not yet been fully explored.

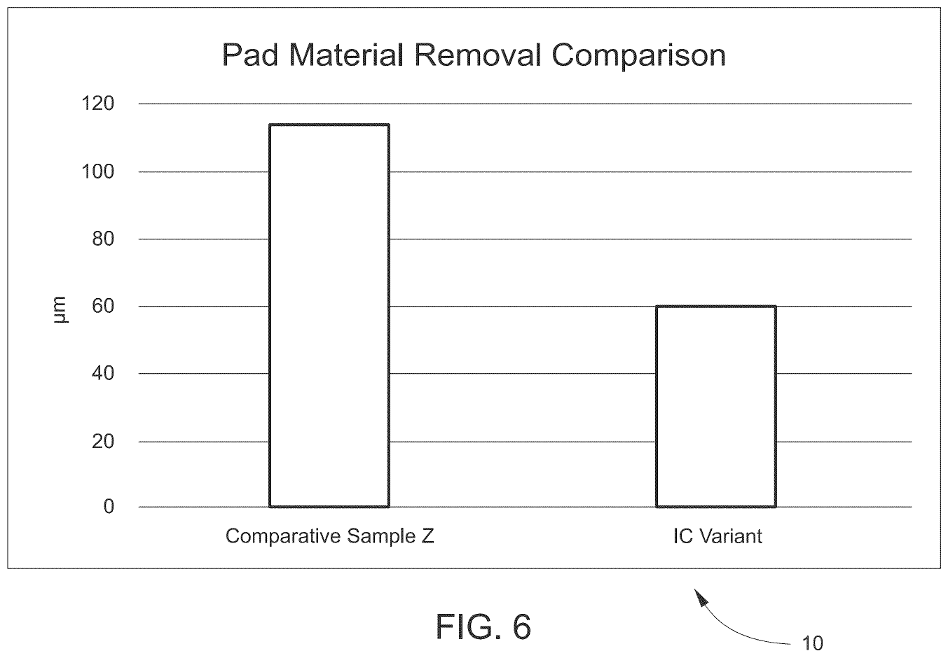

Referring now to FIG. 6, to further demonstrate the unique effects of CMP slurry 10 regarding pad wear rates, a direct testing and measurement technique was employed. An Ikonic IK4250L pad (from Pureon, Inc. of Monroe, NC) was used to prepare samples for polishing by removing 3″ from the middle of 4″ diameter pads. The thickness of the pad was measured by examining a sample coupon removed from the 3″ removed pieces. Cross-sections of these pads were then examined, under a microscope with a scale for comparative purposes. The test samples were then mounted to a weighted puck. Polishing was conducted on a Lapmaster 12-C polisher onto which a MHS grooved pad (MHS15S050GEL from Pureon, Inc. of Monroe, NC, cut down to 12″ diameter) was mounted to provide enhanced abrasion of the Ikonic pad. The platen speed was set to 40 rpm and the arm motor speed to 100 rpm while applying 2.6 psi of downforce during the polishing for both samples. Polishing time was 7 hours for both the Comparative Sample Z and the disclosed CMP Slurry 10 as shown in the data as IC variant formulas. Post-polish measurements of pad wear were done in the same manner as the pre-polish samples, with a sample coupon removed from the post-polish sample and a cross-section measured under a microscope using the same scale.

Comparative Example Z formula: Deionized Water (91.12 wt %); fumed alumina (0.22 wt %); fumed silica (1.13 wt %); alpha alumina (3 wt %); potassium permanganate (3 wt %); and aluminum nitrate (0.50 wt %);

CMP slurry 10, as labeled IC Variant formula: deionized water (88.7 wt %); boehmite alumina (0.78 wt %); fumed silica (0.3 wt %); alpha alumina (4.3 wt %); potassium permanganate (3 wt %); and aluminum nitrate (0.50 wt %).

FIG. 6 further emphasizes the unique ability of CMP slurry 10 to reduce overall pad wear. With the addition of another oxidizer in the aluminum nitrate, and the presence of a greater weight percentage (wt %) of alpha alumina than in Comparative Sample Z, CMP slurry 10 continues to demonstrate significantly less pad wear, despite more abrasive action from the alpha alumina abrasive particles and a more chemically oxidative environment during the polishing process, with the pH of Comparative Sample Z at 3.84 and the IC Variant (CMP slurry 10) pH at 3.72.

In the specification and/or figures, typical embodiments of the disclosure have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

The foregoing description and drawings comprise illustrative embodiments. Having thus described exemplary embodiments, it should be noted by those skilled in the art that the within disclosures are exemplary only, and that various other alternatives, adaptations, and modifications may be made within the scope of the present disclosure. Merely listing or numbering the steps of a method in a certain order does not constitute any limitation on the order of the steps of that method. Many modifications and other embodiments will come to mind to one skilled in the art to which this disclosure pertains having the benefit of the teachings presented in the foregoing descriptions and the associated drawings. Although specific terms may be employed herein, they are used in a generic and descriptive sense only and not for purposes of limitation. Accordingly, the present disclosure is not limited to the specific embodiments illustrated herein but is limited only by the following claims.

1. A chemical mechanical polishing (“CMP”) slurry for reducing polishing pad wear rate comprising:
at least one oxidizer;
a primary abrasive;
a solvent; and
a secondary abrasive that is a mixture of chemicals that yield a stable suspension.

2. The CMP slurry for reducing polishing pad wear rate of claim 1, wherein the CMP slurry is designed and configured to provide:
a pad wear rate of less than 2.0% at a 1-hour polishing time;
the pad wear rate of less than 10.0% at a 4-hour polishing time; or
a combination thereof.

3. The CMP slurry for reducing polishing pad wear rate of claim 2, wherein the CMP slurry is designed and configured to provide:
the pad wear rate of less than 1.0% at the 1-hour polishing time;
the pad wear rate of less than 3.0% at the 4-hour polishing time; or
a combination thereof.

4. The CMP slurry for reducing polishing pad wear rate of claim 1, wherein the CMP slurry is designed and configured to provide a reduced pad wear rate compared to a standard CMP slurry.

5. The CMP slurry for reducing polishing pad wear rate of claim 4, wherein the CMP slurry is designed and configured to provide the reduced pad wear rate compared to the standard CMP slurry while providing a material removal rate (MRR) and a surface roughness (S_{q}) of a workpiece post-polish.

6. The CMP slurry for reducing polishing pad wear rate of claim 5, wherein the CMP slurry is designed and configured to:
reduce the pad wear rate by at least 50% compared to the standard CMP slurry;
provide the material removal rate (MRR) being greater than 4.0 μm/h for a 1-hour polish time; and
provide the surface roughness (Sa) of the workpiece post-polish being less than 2.0 Å.

7. The CMP slurry for reducing polishing pad wear rate of claim 6 wherein the CMP slurry is designed and configured to:
reduce the pad wear rate by at least 75% compared to the standard CMP slurry;
provide the material removal rate (MRR) being greater than 4.5 μm/h for a 1-hour polish time; and
provide the surface roughness (Sa) of the workpiece post-polish being less than 1.5 Å.

8. The CMP slurry for reducing polishing pad wear rate of claim 1, wherein:
the at least one oxidizer is selected from a group consisting of: a permanganate, a perborate, a periodate, a persulfate, a peroxide, a perchlorate, a chlorate, a chlorite, a hypochlorite, a nitrate, a peroxo-compound; and a combination thereof;
the secondary abrasive of the mixture of chemicals that yield the stable suspension is selected from a group consisting of: a boehmite, a fumed silica, and a combination thereof;
the primary abrasive is selected from a group consisting of: a diamond, an alumina, a boron carbide, a silicon carbide, a cerium oxide, a zirconium oxide, a silica, an aluminum oxide hydroxide, a boron nitride, a garnet, a walnut shell, a kaolin, a gibbsite, a titania, a mica, an aluminum bromide, a boron hydride, a magnesium hydroxide, and a combination thereof; or
the solvent is a water including a deionized water.

9. The CMP slurry for reducing polishing pad wear rate of claim 8, wherein:
the at least one oxidizer is selected from the group consisting of: the permanganate, the perborate, the periodate, the persulfate, the peroxide, the perchlorate, the chlorate, the chlorite, the hypochlorite, the nitrate, the peroxo-compound; and the combination thereof;
the secondary abrasive of the mixture of chemicals that yield the stable suspension is selected from the group consisting of: the boehmite, the fumed silica, and the combination thereof;
the primary abrasive is selected from the group consisting of: the diamond, the alumina, the boron carbide, the silicon carbide, the cerium oxide, the zirconium oxide, the silica, the aluminum oxide hydroxide, the boron nitride, the garnet, the walnut shell, the kaolin, the gibbsite, the titania, the mica, the aluminum bromide, the boron hydride, the magnesium hydroxide, and the combination thereof; and
the solvent is the water including the deionized water.

10. The CMP slurry for reducing polishing pad wear rate of claim 1, wherein:
the at least one oxidizer is 0.1-50% by weight of the CMP slurry;
the secondary abrasive of the mixture of chemicals that yield the stable suspension is 0.01-5% by weight of the CMP slurry;
the primary abrasive is 0.01-10% by weight of the CMP slurry; or
the solvent is 35-99.88% by weight of the CMP slurry.

11. The CMP slurry for reducing polishing pad wear rate of claim 10, wherein:
the at least one oxidizer is 0.1-50% by weight of the CMP slurry;
the secondary abrasive of the mixture of chemicals that yield the stable suspension is 0.01-5% by weight of the CMP slurry;
the primary abrasive is 0.01-10% by weight of the CMP slurry; and
the solvent is 35-99.88% by weight of the CMP slurry.

12. The CMP slurry for reducing polishing pad wear rate of claim 11, wherein:
the at least one oxidizer is approximately or equal to 3.0% by weight of the CMP slurry;
the secondary abrasive of the mixture of chemicals that yield the stable suspension is approximately or equal to 0.9% by weight of the CMP slurry;
the primary abrasive is approximately or equal to 3.0% by weight of the CMP slurry; and
the solvent is approximately or equal to 93.1% by weight of the CMP slurry.

13. The CMP slurry for reducing polishing pad wear rate of claim 12, wherein:
the at least one oxidizer is 3.0% by weight of the CMP slurry;
the secondary abrasive of the mixture of chemicals that yield the stable suspension is 0.9% by weight of the CMP slurry and is a combination of a boehmite at 0.6% by weight of the CMP slurry and a fumed silica at 0.3% by weight of the CMP slurry;
the primary abrasive is at 3.0% by weight of the CMP slurry; and
the solvent is water at 92.2% by weight of the CMP slurry.

14. The CMP slurry for reducing polishing pad wear rate of claim 11, wherein:
the at least one oxidizer is a potassium permanganate at approximately or equal to 3.0% by weight of the CMP slurry and an aluminum nitrate at approximately or equal to 0.50% by weight of the CMP slurry;
the secondary abrasive of the mixture of chemicals that yield the stable suspension is a boehmite alumina at approximately or equal to 0.78% by weight of the CMP slurry and a fumed silica at approximately or equal to 0.3% by weight of the CMP slurry;
the primary abrasive is an alpha alumina at approximately or equal to 4.3% by weight of the CMP slurry; and
the solvent is deionized water at approximately or equal to 91.12% by weight of the CMP slurry.

15. The CMP slurry for reducing polishing pad wear rate of claim 14, wherein:
the at least one oxidizer is a potassium permanganate at 3.0% by weight of the CMP slurry and an aluminum nitrate at 0.50% by weight of the CMP slurry;
the secondary abrasive of the mixture of chemicals that yield the stable suspension is a boehmite alumina at 0.78% by weight of the CMP slurry and a fumed silica at 0.3% by weight of the CMP slurry;
the primary abrasive is an alpha alumina at 4.3% by weight of the CMP slurry; and
the solvent is deionized water at 91.12% by weight of the CMP slurry.

16. The CMP slurry for reducing polishing pad wear rate of claim 1 being designed and configured to contain abrasive particles at neutral pH for the polishing of hard substrates such as silicon, silicon carbide (SiC), sapphire, diamond, gallium nitride (GaN) or other materials with a Knoop hardness greater than or equal to 1000 used in combination with polyurethane pads.

17. The CMP slurry for reducing polishing pad wear rate of claim 1 being designed and configured to improve compatibility between the slurry composition and the pad, wherein the use of a unique slurry composition which requires less extreme pH and fewer additives allows for the realization of lower pad wear rate while maintaining an acceptable material removal rate (MRR) and surface roughness (S_{q}).

18. A chemical mechanical polishing (“CMP”) slurry for reducing polishing pad wear rate comprising:
at least one oxidizer, the at least one oxidizer is selected from a group consisting of: a permanganate, a perborate, a periodate, a persulfate, a peroxide, a perchlorate, a chlorate, a chlorite, a hypochlorite, a nitrate, a peroxo-compound, and a combination thereof, the at least one oxidizer is 0.1-50% by weight of the CMP slurry;
a primary abrasive, the primary abrasive is selected from a group consisting of: a diamond, an alumina, a boron carbide, a silicon carbide, a cerium oxide, a zirconium oxide, a silica, an aluminum oxide hydroxide, a boron nitride, a garnet, a walnut shell, a kaolin, a gibbsite, a titania, a mica, an aluminum bromide, a boron hydride, a magnesium hydroxide, and a combination thereof, the primary abrasive is 0.01-10% by weight of the CMP slurry;
a solvent that is a deionized water, the solvent is 35-99.88% by weight of the CMP slurry;
a secondary abrasive that is a mixture of chemicals that yield a stable suspension and is selected from a group consisting of: a boehmite, a fumed silica, and a combination thereof, the secondary abrasive of the mixture of chemicals that yield the stable suspension is 0.01-5% by weight of the CMP slurry;
wherein the CMP slurry is designed and configured to provide:
a pad wear rate of less than 1.0% at a 1-hour polishing time;
the pad wear rate of less than 3% at a 4-hour polishing time;
wherein the CMP slurry is designed and configured to provide a reduced pad wear rate compared to a standard CMP slurry, while providing a material removal rate (MRR) and a surface roughness (Sa) of a workpiece post-polish, wherein the CMP slurry is designed and configured to:
reduce the pad wear rate by at least 75% compared to the standard CMP slurry;
provide the material removal rate (MRR) being greater than 4.5 μm/h for a 1-hour polish time; and
provide the surface roughness (S_{q}) of the workpiece post-polish being less than 1.5 Å.

19. A method of chemical mechanical polishing (“CMP”) of a hard substrate comprising:
providing a CMP slurry for reducing polishing pad wear rate comprising:
at least one oxidizer;
a primary abrasive;
a solvent;
a secondary abrasive that is a mixture of chemicals that yield a stable suspension; and
polishing the hard substrate with the provided CMP slurry, wherein the CMP slurry is designed and configured to provide:
a pad wear rate of less than 2.0% at a 1-hour polishing time;
the pad wear rate of less than 10.0% at a 4-hour polishing time; or
a combination thereof.

20. The method of CMP of the hard substrate of claim 19, wherein the hard substrate is a workpiece made of silicon, silicon carbide (SiC), sapphire, diamond, gallium nitride (GaN), or hard optical materials, wherein the workpiece having a Knoop hardness greater than or equal to 1000; and
wherein, the provided CMP slurry is used with polyurethane pads for polishing the workpiece.
